(19) United States
(12) Patent Application Publication
(10) Pub. No.: US 2023/0246006 A1
(43) Pub. Date: Aug. 3, 2023

(54) JOINT STRUCTURE

(71) Applicant: TDK CORPORATION, Tokyo (JP)

(72) Inventors: Ryohei KASAI, Tokyo (JP); Takashi WATANABE, Tokyo (JP); Susumu TANIGUCHI, Tokyo (JP); Tomohisa MITOSE, Tokyo (JP); Yuhei HOTTA, Tokyo (JP)

(73) Assignee: TDK CORPORATION, Tokyo (JP)

(21) Appl. No.: 18/162,183

(22) Filed: Jan. 31, 2023

(30) Foreign Application Priority Data
Feb. 2, 2022 (JP) 2022-014673

(51) Int. Cl. H01L 25/075; H01L 23/00

(52) U.S. Cl. CPC H01L 25/0753; H01L 24/05; H01L 24/13; H01L 24/16; H01L 2224/13111; H01L 2224/13144; H01L 2224/16225; H01L 2224/05073; H01L 2224/05144; H01L 2224/05139; H01L 2224/05147; H01L 2224/05155; H01L 2224/05164; H01L 2224/16503; H01L 2924/01327; H01L 2924/12041

(57) ABSTRACT

A joint structure, in which an electronic component and a wiring substrate are joined to each other, includes: a first layer being provided on one side of the electronic component and the wiring substrate, and being composed of a first metal containing Sn; a second layer being provided on the other side of the electronic component and the wiring substrate, and being composed of a second metal that forms an intermetallic compound with Sn; and a third layer being provided at a joint interface between the first layer and the second layer, and being composed of an intermetallic compound of the first metal and the second metal. An average thickness of the third layer is 0.1 μm or more to 0.5 μm or less.

### CROSS-REFERENCE TO RELATED APPLICATIONS

This application is based upon and claims the benefit of priority from Japanese Patent Application No. 2022-014673, filed on Feb. 2, 2022. The entire contents of which are incorporated herein by reference.

### BACKGROUND

### Field

The present invention relates to a joint structure.

### Description of the Related Art

In recent years, computerization has progressed, and accordingly, the development of a technique for mounting an electronic component on a substrate is underway. For example, until now, in assembling a fine electronic component, gold is employed for a terminal of the electronic component, Sn is applied to a facing wiring substrate side via plating or thin film deposition, and joining is performed by solder joining or diffusion joining When an electronic component and a wiring substrate are joined to each other via Au plating and Sn plating, an intermetallic compound of Au and Sn tends to be formed at a joint interface due to eutectic reaction. For example, in Japanese Unexamined Patent Publication No. 2017-216308, a layer containing an AuSn alloy is set to a thickness within a predetermined range.

### SUMMARY

Here, since the intermetallic compound is hard, even when a stress acts on a joint structure, the joint structure is difficult to bend, whereas the breakage strength decreases since the joint structure is brittle, which is a problem.

An object of the present invention is to provide a joint structure having high breakage strength.

According to the present invention, there is provided a joint structure in which an electronic component and a wiring substrate are joined to each other, the structure including: a first layer being provided on one side of the electronic component and the wiring substrate, and being composed of a first metal containing Sn; a second layer being provided on the other side of the electronic component and the wiring substrate, and being composed of a second metal that forms an intermetallic compound with Sn; and a third layer being provided at a joint interface between the first layer and the second layer, and being composed of an intermetallic compound of the first metal and the second metal. An average thickness of the third layer is 0.1 μm or more to 0.5 μm or less.

The joint structure according to the present invention includes the third layer, which is composed of the intermetallic compound, between the first layer composed of the first metal containing Sn and the second layer composed of the second metal that forms the intermetallic compound with Sn. Here, the metals are soft materials that are generally ductile since the metals have metallic bonding, whereas the intermetallic compound is a hard and brittle material. For this reason, the average thickness of the third layer composed of the intermetallic compound is set to 0.1 μm or more to 0.5 μm or less. Since the third layer which is thin is provided, the intermetallic compound can make it difficult to bend the joint structure, and the metals sandwiching the intermetallic compound therebetween can make it difficult to break the joint structure. As described above, it is possible to obtain the joint structure having high breakage strength and high reliability.

The second metal may be any metal of Au, Cu, Ni, Ag, and Pd, or an alloy of at least two selected from Au, Cu, Ni, Ag, and Pd. In this case, the second layer easily forms the intermetallic compound with Sn.

The second metal may be a metal containing at least Au. The breakage strength is further increased by sandwiching the third layer, which is thin, between the second layer of Au and the first layer of Sn, Au being soft and having a particularly low Young's modulus among metals.

The third layer may contain AuSn₄. Even when the intermetallic compound is AuSn₄ that has low hardness and that is likely to crack, among AuSn intermetallic compounds, since the intermetallic compound is sandwiched between the soft metals, the joint structure in which the third layer is unlikely to bend and crack is obtained, so that the breakage strength can be further increased.

The electronic component may be an LED. Accordingly, thereafter, the wiring substrate to which the LED is attached is assembled into a display or the like through many steps, but the occurrence of a defect caused by breakage in the steps can be suppressed.

According to the present invention, it is possible to provide the joint structure having high breakage strength.

### BRIEF DESCRIPTION OF THE DRAWINGS

FIG. 1 is a schematic cross-sectional view showing a mounting substrate including a joint structure according to an embodiment of the present invention.

FIG. 2 is a schematic cross-sectional view showing a wiring substrate to which the joint structure according to the embodiment of the present invention is applied.

FIG. 3 is a view showing one example of an SEM image.

FIGS. 4A and 4B are views for describing a method for joining an electronic component and the wiring substrate.

FIG. 5 is a table showing measurement results of Examples and Comparative Examples.

### DETAILED DESCRIPTION

In the following description, with reference to the drawings, the same reference numbers are assigned to the same components or to similar components having the same function, and overlapping description is omitted.

It is to be understood that not all aspects, advantages and features described herein may necessarily be achieved by, or included in, any one particular example. Indeed, having described and illustrated various examples herein, it should be apparent that other examples may be modified in arrangement and detail.

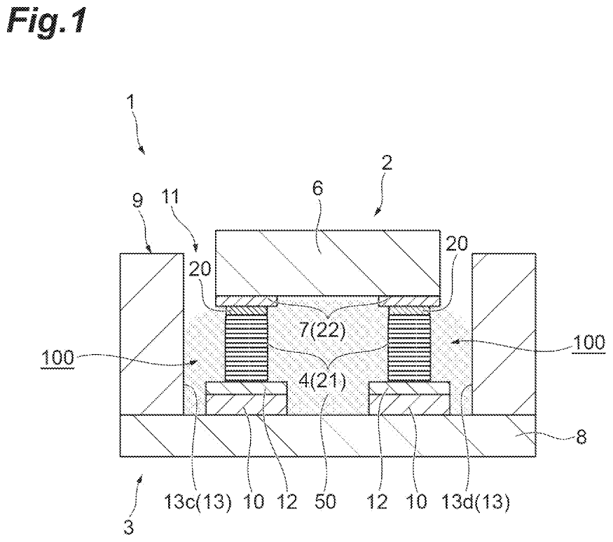

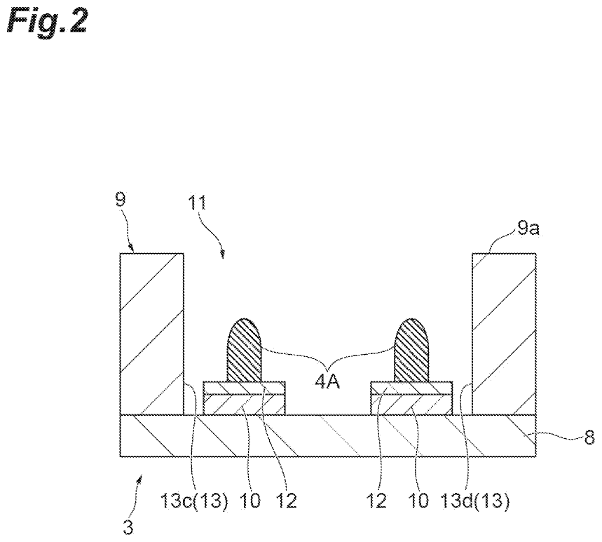

A joint structure 100 according to an embodiment of the present invention will be described with reference to FIGS. 1 and 2. FIG. 1 is a schematic cross-sectional view showing a mounting substrate 1 including the joint structure 100 according to the embodiment of the present invention. FIG. 2 is a schematic cross-sectional view showing a wiring substrate 3 to which the joint structure 100 according to the embodiment of the present invention is applied.

As shown in FIG. 1, the mounting substrate 1 includes an electronic component 2 and the wiring substrate 3. The mounting substrate 1 is configured by mounting the electronic component 2 on the wiring substrate 3 via a joining material 4.

The electronic component 2 includes a body portion 6 and a pair of terminals 7. The body portion 6 is a member that performs the function of the electronic component 2. The terminals 7 are metal portions formed on a main surface of the body portion 6. The electronic component 2 is formed of, for example, a micro-LED or the like. The micro-LED is a component that emits light according to an input from the wiring substrate 3.

The wiring substrate 3 includes a base material 8, a wall 9, and a pair of terminals 10. The base material 8 is a flat plate-shaped body portion of the wiring substrate 3. The wall 9 is a member formed of an insulator formed on an upper surface of the base material 8. As the material of the wall 9, for example, resin materials such as epoxy resin, acrylic resin, phenolic resin, melamine resin, urea resin, or alkyd resin is employed. Particularly preferably, as the material of the wall 9, epoxy resin or acrylic resin is employed. The terminals 10 are metal portions formed on a main surface of the base material 8. As the material of the terminal 10, Ni, Cu, Ti, Cr, Al, Mo, Pt, Au, an alloy of at least two selected therefrom, or the like is employed. A conductive film 12 is formed on an upper surface of the terminal 10. A film of Ti, Cu, Ni, Al, Mo, Cr, Ag, or the like as the material of the conductive film 12, a film in which metal particles and a binder are mixed, or the like is employed.

The joining material 4 is a member that joins the terminal 7 of the electronic component 2 and the terminal 10 of the wiring substrate 3. The joining material 4 functions as a solder. Before assembly, the wiring substrate 3 includes a joining material 4A disposed on an upper surface of the conductive film 12. During assembly, solder joining is performed after the terminal 10, the conductive film 12, the joining material 4, and the terminal 7 are stacked. Therefore, an IMC layer 20 of an intermetallic compound (IMC) in which metals of the terminal 10, the conductive film 12, the joining material 4, and the terminal 7 react with each other is formed at a connection interface between the joining material 4 and the terminal 7.

A recessed portion 11 is formed in the wall 9. The recessed portion 11 is formed of a through-hole penetrating through the wall 9. Accordingly, the upper surface of the base material 8 is exposed on a bottom side of the recessed portion 11. The recessed portion 11 has a rectangular shape when viewed in a thickness direction of the wiring substrate 3. The terminal 7, the terminal 10, the conductive film 12, and the joining material 4 are surrounded by the wall 9 by being disposed inside the recessed portion 11 formed in the wall 9. Slight gaps are formed between four inner surfaces of the recessed portion 11 (namely, inner surfaces of the wall 9) and the terminal 7, the terminal 10, the conductive film 12, and the joining material 4.

Inside the recessed portion 11, a constituent material 50 is formed between the wall 9 and each of the electronic component 2 and the joining material 4. Accordingly, support by the constituent material 50 can make it for the electronic component 2 to be unlikely to peel off from the wiring substrate 3. In addition, a force applied to the electronic component 2, the joining material 4, or the terminals 7 and 10 is reduced, so that reliability can be improved. As the material of the constituent material 50, for example, epoxy resin, acrylic resin, phenolic resin, melamine resin, urea resin, alkyd resin, a mixture thereof, or a mixture of the above resin material and SiOx, ceramics, or the like is employed. Particularly preferably, as the material of the constituent material 50, epoxy resin or acrylic resin is employed.

The joint structure 100 according to the present embodiment includes the terminal 10, the conductive film 12, the joining material 4, the IMC layer 20, and the terminal 7 that are stacked in order from the upper surface of the base material 8. The joint structure 100 includes a first layer 21 that is provided on one side of the electronic component 2 and the wiring substrate 3, and that is composed of a first metal containing Sn. In addition, the joint structure 100 includes a second layer 22 that is provided on the other side of the electronic component 2 and the wiring substrate 3, and that is composed of a second metal which forms an intermetallic compound with Sn.

In the present embodiment, the terminal 7 of the electronic component 2 corresponds to the second layer 22, and the joining material 4 on a wiring substrate 3 side corresponds to the first layer 21. Therefore, the IMC layer 20 is provided at a joint interface between the terminal 7 and the joining material 4, and is composed of an intermetallic compound of the first metal and the second metal.

The first metal of the joining material 4 may contain Sn, and may be composed of an alloy containing Sn. The first metal may contain an element that lowers a melting point of Sn, in addition to Sn. For example, Bi or the like is provided as the element that lowers the melting point of Sn.

The second metal of the terminal 10 is any metal of Au, Cu, Ni, Ag, and Pd, or an alloy of at least two selected therefrom. The second metal may be a metal containing at least Au. In this case, the IMC layer 20 contains AuSn₄.

An average thickness of the IMC layer 20 is preferably 0.1 μm or more, more preferably 0.2 μm or more. Since a surface of the joining material 4 containing Sn is rough, the average thickness of the IMC layer 20 is set to the above dimensions or more, so that joinability between the joining material 4 and the terminal 7 is ensured and conductivity is ensured. The average thickness of the IMC layer 20 is preferably 0.5 μm or less, more preferably 0.4 μm or less. Joint reliability can be improved by setting the average thickness of the IMC layer 20, which is brittle, to the dimensions or less.

A method for measuring an average thickness of the IMC layer 20 described above will be described. First, the vicinity of the center of the obtained joint structure 100 is cut perpendicular to the wiring substrate 3, phase identification of each layer is performed from an element ratio obtained by SEM-EDS measurement, and an average thickness of the IMC layer 20 is measured from an SEM image. Specifically, a plurality of points (for example, five points) on an interface between the second layer 22 and the IMC layer 20 are taken at equal intervals, and a shortest distance from each point to the interface between an interface between the first layer 21 and the IMC layer 20 is measured. An average of a plurality (five) of the distances is the average thickness of the IMC layer 20. The average thickness based on the shortest distances of the plurality of points may be 0.1 μm or more to 0.5 μm or less.

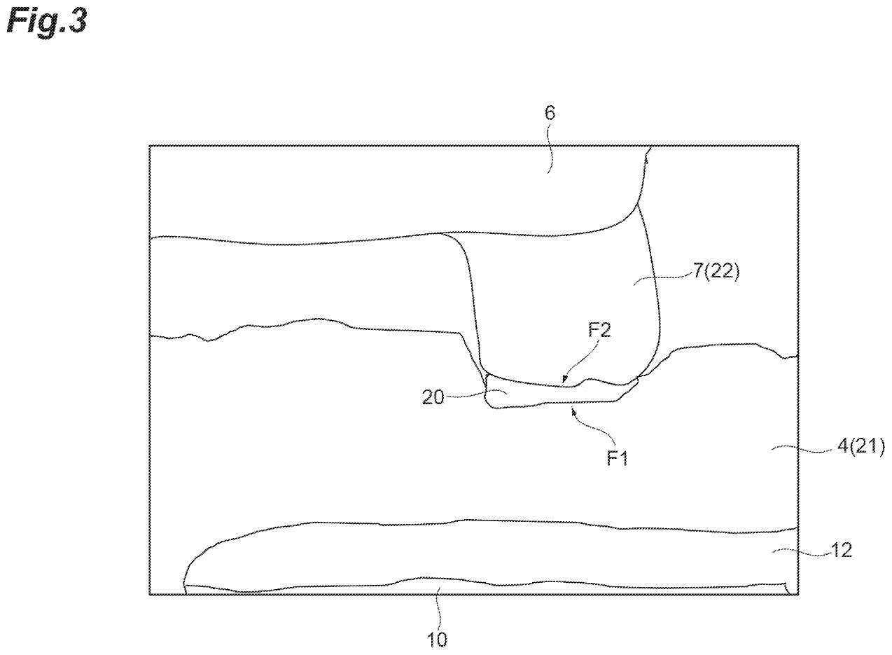

An example of an SEM image is shown in FIG. 3. The interface between the first layer 21 and the IMC layer 20 is indicated by “F1”. The interface between the second layer 22 and the IMC layer 20 is indicated by “F2”. A plurality of points are taken at equal intervals from the interface F2.

As the method for measuring an average thickness of the IMC layer 20, a method may be employed in which an area of the IMC layer 20 is obtained from image analysis and an average thickness is calculated by dividing the area by a length of the interface F2. The average thickness based on the measurement method may be 0.1 μm or more to 0.5 μm or less.

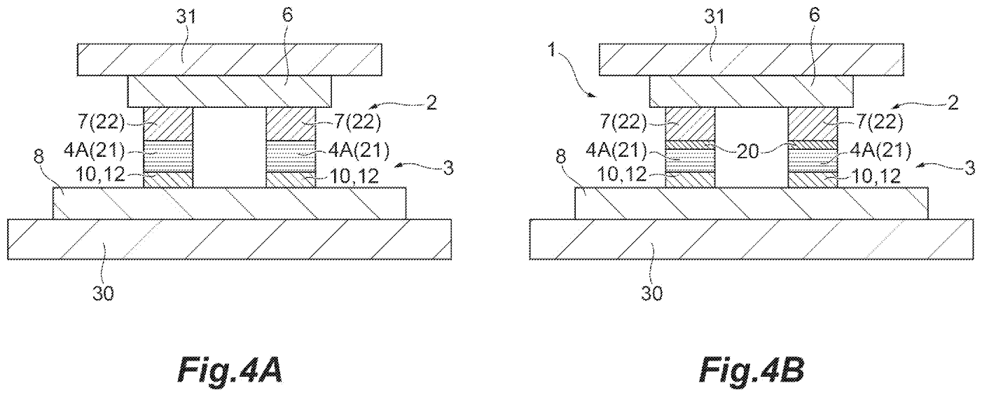

Next, a method for joining the electronic component 2 and the wiring substrate 3 will be described with reference to FIGS. 4A and 4B. First, as shown in FIG. 4A, the terminal 7 of the electronic component 2 is placed on the joining material 4A of the wiring substrate 3. Here, when heating is performed for a long period of time (several minutes) at a temperature higher than the melting point of Sn, the entirety becomes a eutectic structure, so that it is difficult to form the IMC layer 20, which is thin, in the joint structure 100. Therefore, when heating is performed for a short period of time and the temperature reaches a temperature at which the first metal of the joining material 4A containing Sn melts, rapid cooling is performed. For example, rapid heating and rapid cooling may be performed in which only the joining material 4A containing Sn is instantaneously melted by applying pulsed electromagnetic waves. As shown in FIG. 4A, a cooling plate 30 is brought into contact with the wiring substrate 3 including the joining material 4A containing Sn, and a heating plate 31 is brought into contact with the electronic component 2 including the terminal 7 containing the second metal that forms an intermetallic compound with Sn. Then, temperature control may be performed such that only a contact portion between the terminal 7 and the joining material 4A is melted to form the IMC layer 20 (refer to FIG. 4B). Incidentally, the joining method is not particularly limited, but joining may be performed using light energy.

Next, actions and effects of the joint structure 100 according to the present embodiment will be described.

The joint structure 100 according to the present embodiment includes the IMC layer 20, which is composed of an intermetallic compound, between the first layer 21 composed of the first metal containing Sn and the second layer 22 composed of the second metal that forms an intermetallic compound with Sn. Here, the metals are soft materials that are generally ductile since the metals have metallic bonding. On the other hand, the intermetallic compound is a hard and brittle material. For this reason, the average thickness of the IMC layer 20 composed of the intermetallic compound is set to 0.1 μm or more to 0.5 μm or less. Since the IMC layer 20 which is thin is provided, the intermetallic compound can make it difficult to bend the joint structure 100, and the metals sandwiching the intermetallic compound therebetween can make it difficult to break the joint structure 100. As described above, it is possible to obtain the joint structure 100 having high breakage strength and high reliability.

The second metal is any metal of Au, Cu, Ni, Ag, and Pd, or an alloy of at least two selected from Au, Cu, Ni, Ag, and Pd. In this case, the second layer 22 easily forms an intermetallic compound with Sn.

The second metal may be a metal containing at least Au. The breakage strength is further increased by sandwiching a third layer, which is thin, between the second layer 22 of Au and the first layer 21 of Sn, Au being soft and having a particularly low Young's modulus among metals.

The IMC layer 20 may contain AuSn₄. Even when the intermetallic compound is AuSn₄ that has low hardness and that is likely to crack, among AuSn intermetallic compounds, since the intermetallic compound is sandwiched between the soft metals, the joint structure 100 in which the IMC layer 20 is unlikely to bend and crack is obtained, so that the breakage strength can be further increased.

The electronic component 2 may be an LED. Accordingly, thereafter, the wiring substrate to which the LED is attached is assembled into a display or the like through many steps, but the occurrence of a defect caused by breakage in the steps can be suppressed.

The present invention is not limited to the above-described embodiment.

In the above-described embodiment, the layer on the wiring substrate 3 side is the first layer 21, and the layer on an electronic component 2 side is the second layer 22. Instead, the layer on the wiring substrate 3 side may be the second layer 22, and the layer on the electronic component 2 side may be the first layer 21.

In addition, the disposition, the sizes, or the number of the layers of the joint structure is not particularly limited, and may be appropriately changed within the concept of the present invention.

### EXAMPLES

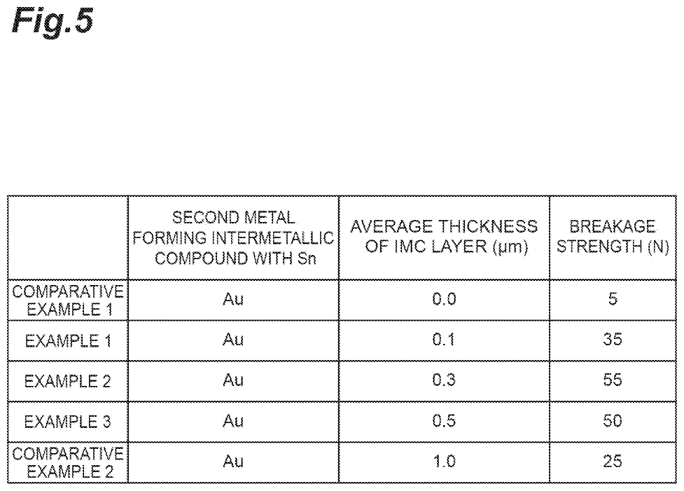

Examples 1 to 3 and Comparative Examples 1 and 2 will be described with reference to FIG. 5. However, the present invention is not limited to Examples. First, a method for manufacturing the mounting substrate 1 according to Examples and Comparative Examples will be described. An LED was prepared as the electronic component 2, and the terminal 7 of Au was formed on the LED. After an electrodeposited layer of the conductive film 12 of Ni was formed on the terminal 10 of Cu on a substrate side, the joining material 4A of Sn was formed on the conductive film 12. In a state where the terminal 7 of Au of the electronic component 2 and the joining material 4A of Sn of the wiring substrate 3 are brought into contact with each other, the thickness of the IMC layer 20 was controlled by bringing the heating plate 31 at 300° C. to 310° C. into contact with the electronic component 2 side for three minutes while bringing the cooling plate 30 into contact with the wiring substrate 3 such that the wiring substrate 3 side is always at 50° C., thereby obtaining the mounting substrate 1. The mounting substrates 1 of Examples 1 to 3 and Comparative Examples 1 and 2 were manufactured under the same conditions except that average thicknesses of the IMC layers 20 were different from each other. The average thicknesses of the IMC layers 20 were measured by the above-described method in which phase identification of each layer was performed from an element ratio obtained by SEM-EDS measurement and the average thickness of the IMC layer 20 was measured from an SEM image. The average thicknesses of the IMC layers 20 are shown in FIG. 5. Next, in the mounting substrates 1 of Examples 1 to 3 and Comparative Examples 1 and 2, breakage strength was measured for LED joint portions using a bond tester. Measurement results are shown in FIG. 5.

In Comparative Example 1, since the IMC layer 20 was not present, it was considered that joining was not properly performed and breakage was likely to occur. In Comparative Example 2, since the IMC layer 20 that was brittle was thick, it was considered that breakage was likely to occur. In Examples 2 and 3, since the IMC layer 20 was thinly present, the breakage strength was high. In Example 1, since the IMC layer 20 was thinly present, the breakage strength was higher than in Comparative Example 1, but compared to Examples 2 and 3, the terminal 7 of Au and the joining material 4A of Sn was not sufficiently joined to each other, and the breakage strength was low.

### Embodiments

1. A joint structure in which an electronic component and a wiring substrate are joined to each other, the structure comprising:

a first layer being provided on one side of the electronic component and the wiring substrate, and being composed of a first metal containing Sn;

a second layer being provided on the other side of the electronic component and the wiring substrate, and being composed of a second metal that forms an intermetallic compound with Sn; and a third layer being provided at a joint interface between the first layer and the second layer, and being composed of an intermetallic compound of the first metal and the second metal, po1 wherein an average thickness of the third layer is 0.1 μm or more to 0.5 μm or less.

2. The joint structure according to embodiment 1, wherein the second metal is any metal of Au, Cu, Ni, Ag, and Pd, or an alloy of at least two selected from Au, Cu, Ni, Ag, and Pd.

3. The joint structure according to embodiment 2, wherein the second metal is a metal containing at least Au.

4. The joint structure according to any one of embodiments 1 to 3, wherein the third layer contains AuSn₄.

5. The joint structure according to any one of embodiments 1 to 4, wherein the electronic component is an LED.

### REFERENCE SIGNS LIST

2: electronic component, 3: wiring substrate, 20: IMC layer (third layer), 21: first layer, 22: second layer, 100: joint structure.

What is claimed is:

1. A joint structure in which an electronic component and a wiring substrate are joined to each other, the structure comprising:
a first layer being provided on one side of the electronic component and the wiring substrate, and being composed of a first metal containing Sn;
a second layer being provided on the other side of the electronic component and the wiring substrate, and being composed of a second metal that forms an intermetallic compound with Sn; and
a third layer being provided at a joint interface between the first layer and the second layer, and being composed of an intermetallic compound of the first metal and the second metal, wherein an average thickness of the third layer is 0.1 μm or more to 0.5 μm or less.

2. The joint structure according to claim 1,
wherein the second metal is any metal of Au, Cu, Ni, Ag, and Pd, or an alloy of at least two selected from Au, Cu, Ni, Ag, and Pd.

3. The joint structure according to claim 2,
wherein the second metal is a metal containing at least Au.

4. The joint structure according to claim 1,
wherein the third layer contains AuSn₄.

5. The joint structure according to claim 1,
wherein the electronic component is an LED.
